(19) United States
(12) Patent Application Publication
(10) Pub. No.: US 2011/0079278 A1
(43) Pub. Date: Apr. 7, 2011

(54) Method of Manufacturing a Photovoltaic Compound Semiconductor Printing Solution to Produce Solar Cells

(76) Inventor: John DUNKLEY, British Columbia (CA)

(21) Appl. No.: 12/866,653

(22) PCT Filed: Feb. 6, 2009
(86) PCT No.: PCT/CA2009/000165

§ 371 Date: Nov. 19, 2010

Related U.S. Application Data
(62) Division of application No. 61/026,642, filed on Feb. 6, 2008.

(51) Int. Cl. H01L 31/0224; H01L 31/0296; H01L 31/18

(52) U.S. Cl. 136/256; 257/42; 438/84; 257/E31.018

(57) ABSTRACT

A photovoltaic semiconductor solution comprising at least an equimolar mixture of cadmium, tellurium, gallium and indium; propylene glycol flux; carbon; resin in an organic solvent; strontium titanate; and high molecular weight polymer. The photovoltaic semiconductor solution provides charged free electrons on application of light to the photovoltaic semiconductor solution. Another embodiment relates to a solar cell comprising first and second electrode layers; a photovoltaic semiconductor layer disposed between the first and second electrodes; a first membrane disposed between the first electrode and the semiconductor layer and a second membrane disposed between the second electrode and the semiconductor layer. The first membrane is an electron acceptor layer and the second membrane in an insulator. The PV semiconductor layer includes the PV semiconductor solution. Each of the layers of the solar cell are formed on a substrate. Photoelectric power is generated due to light that is incident from the first electrode layer.

### RELATED APPLICATIONS

This application claims the benefit of U.S. Provisional Patent Application No. 61/026,642 filed Feb. 8, 2008.

### FIELD OF THE INVENTION

The invention relates to solar cells, and more particularly, to methods of producing solar cells.

### BACKGROUND OF THE INVENTION

A solar cell or photovoltaic cell is a device that converts solar energy into electricity using the photovoltaic effect. Assemblies of these cells are often used to make solar panels, solar modules, or photovoltaic arrays. Solar cells are generally classified into two different categories, crystalline silicon and thin-film solar cells. The first generation of solar cells are crystalline silicon cells (wafer silicon) that have a large-area, and are high quality, single junction devices. Manufacture of these solar cells is costly and requires a large labour input however, these solar cells have a relatively high energy conversion, at least about 20%. The second generation of solar cells are thin-film solar cells that install one or more thin layers (thin films) of photovoltaic material onto a substrate. Many different photovoltaic materials are deposited using various deposition methods on a variety of substrates. Thin film solar cells are usually categorized according to the photovoltaic material used, for example: cadmium telluride (CdTe), copper indium gallium selenide (CIS or CIGS), dye-sensitized solar cell (DSC), or, in particular, thin-film silicon (TF-Si). Solar cells made from thin-film silicon materials tend to have lower energy conversion efficiency and are costly to manufacture.

In general, when manufacturing semiconductor solar cells, it is important that their compound semiconductor membrane and electrode layers have uniform thickness, a smooth surface, and lack pinholes to facilitate the adherence of the electrode layer to the substrate and improve light transmittance, decrease sheet resistance and increase the photocurrent of the cell. If there are pinholes in the semiconductor membrane and electrode layers, the pinholes may cause internal short circuits or current leakage, decreasing the solar cell performance. One commonly used method of constructing solar cells is to use a screen-printing process. Screen-printing is well known and is simply the process of squeezing ink through a series of mesh screens onto a substrate, such as plastic, glass, textiles, vinyl, wood, metal, cork, etc. One advantage of screen-printing is that it can be applied on almost any type of material. The screen is generally produced through a process that involves “burning” an image onto a screen in a dark room. Screen-printed solar cells were first developed in the early 1970's and are commonly used in terrestrial photovoltaic modules.

### BRIEF SUMMARY OF THE INVENTION

A new solar cell and method of manufacturing a solar cell forming an active photovoltaic (PV) semiconductor layer between two membranes and a positive and a negative electrode layer is provided.

One exemplary embodiment is directed to a photovoltaic semiconductor solution comprising at least an equimolar mixture of cadmium, tellurium, gallium and indium; propylene glycol flux; carbon; resin in an organic solvent; strontium titanate; and a high molecular weight polymer. The photovoltaic semiconductor solution provides charged free electrons on application of light to the photovoltaic semiconductor solution.

Another exemplary embodiment is directed to a solar cell comprising a first electrode layer and a second electrode layer; a photo voltaic (PV) semiconductor layer disposed between the first and second electrodes; a first membrane disposed between the first electrode and the semiconductor layer; a second membrane disposed between the second electrode and the semiconductor layer. The first membrane is an electron acceptor layer and the second membrane in an insulator. The PV semiconductor layer includes a PV semiconductor solution comprising at least an equimolar mixture of cadmium, tellurium, gallium and indium. Each of the layers of the solar cell are formed on a substrate and photoelectric power is generated due to light that is incident from the first electrode layer.

Another exemplary embodiment is directed to a method of manufacturing a photovoltaic semiconductor solution comprising the steps of:
making a first solution comprising at least one transition metal dissolved in a polar protic solvent; tellurium; a strong polar acid, preferably having a dielectric constant in the range of about 70-120; propylene glycol; and a stabilizing agent;
making a second solution comprising:
   solution 2A comprising a high molecular weight polymer; and an ether, that acts as thickener and stabilizer;
   solution 2B comprising a mixture of at least one polar protic solvent
   soluable in water; at least one fatty acid; and propylene glycol; and dissolving said solution 2B in a cyanoethyl starch; and
      solution 2C comprising
         solution 2C-1 comprising titanium dioxide, suspended in a polar protic solvent having the pH adjusted by the addition of a quaternary ammonium salt;
         solution 2C-2 comprising at least one polar aprotic solvent, a strong oxidizing agent having an ability to initiate radicals, and a non-polar aromatic hydrocarbon solvent; and
         an alkali stabilizer;
making a third solution comprising at least one polar aprotic solvent; a polymer that acts as an electron acceptor; titanium dioxide; titanium isopropoxide; the salt of at least one alkali metal; and at least one non-polar solvent;
making a fourth solution comprising:
   solution 4A comprising a strong polar acid, a polar protic solvent; at least one highly conductive metal; at least one semi-metal; at least one poor metal; and a non-polar solvent;
   solution 4B comprising at least one transition metal; at least one non-polar solvent; and cesium oxide; and
   at least one semi-conductor non-metal that is photovoltaic and photoconductive;
making said fifth solution comprising mixing at least between about 58-61 ml of said third solution and between at least about 1.5-1.75 g of said second solution;
making said sixth solution comprising mixing at least between about 50-55 ml of said first solution and between at least about 45-50 ml of said fourth solution; and
making said photovoltaic semiconductor solution comprising mixing at least between about 56-59 ml of said fifth solution and at least between about 61-73 ml of said sixth solution. Each of the first, second, third, fourth, fifth, sixth, and PV solutions is preferably stored in a nitrogen atmosphere.
An alternative exemplary embodiment is directed to a method of manufacturing a photovoltaic semiconductor solution comprising the steps of:
making a first solution comprising:
   between about 25-30 ml of solution 1A comprising between about 22-27 mg cadmium, distilled water, between about 4-8 ml sulphuric acid, between about 12-15 mg tellurium and between about 30-40 ml dimethyl formamide; and
   between about 10-18 ml of solution 1B comprising 20-25 mg cadmium sulphide, 11-15 mg cadmium chloride, distilled water, 35-39 ml propylene glycol, 11-14 mg carbon and 6-10 ml trioctylphosphine;
making a second solution comprising:
   solution 2A comprising between about 0.75-1 g of a high molecular weight polymer; and between about 1.36-1.42 g of a 10-13% solution of hydroxypropyl cellulose (HPC) dissolved in distilled water; and
   between about 4-5 ml of solution 2B comprising between about 25-28% of butyl carbitol acetate, between about 10-12% of oleic acid and between about 12-14% of propylene glycol; and dissolving said solution 2B in about 90-100% cyanoethyl starch;
   between about 1.5-1.6 g of solution 2C comprising
      solution 2C1 comprising between about 1.18-1.3 g of titanium dioxide suspended in distilled water, having the pH adjusted by the addition of tetramethylammonium hydroxide;
      solution 2C2 comprising between about 100-110 ml of 99-99.9% tetrahydrofuran, between about 50-55 g of ammonium persulfate and between about 7-9 ml of toluene; and
      solution 2C3 comprising between about 5-8 ml strontium hydroxide suspended in distilled water;
making a third solution comprising between about 41-45 ml tetrahydrofuan, 0.41-0.5 g PCBM, 25-28 mg titanium dioxide, 15-19 mg titanium isopropoxide, 10-13 ml 1,2 dichlorobenzene and 7-8 mg cesium floride;
making a fourth solution comprising:
   solution 4A comprising between about 10-14 ml sulphuric acid, distilled water, between about 40-43 mg copper, between about 10-12 ml chloroform, between about 32-35 ml gallium and between about 5-7 ml indium; and
   solution 4B comprising between about 30-33 mg iridium, distilled water, between about 15-17 ml ethyl acetate, between about 8-11 mg cesium oxide and between about 10-15 ml chlorobenzene;
   mixing between about 10-12 mg selenium and about equal parts of said solution 4A and said solution 4B;
making said fifth solution comprising mixing at least between about 58-61 ml of said third solution and between at least about 1.5-1.75 g of said second solution;
making said sixth solution comprising mixing at least between about 50-55 ml of said first solution and between at least about 45-50 ml of said fourth solution; and
making said photovoltaic semiconductor solution comprising mixing at least between about 56-59 ml of said fifth solution and at least between about 61-73 ml of said sixth solution. Each of the first solution, second solution, third solution, fourth solution, fifth solution, sixth solution and PV solution is preferably stored in a nitrogen atmosphere.
A further exemplary embodiment is directed to a method of manufacturing a solar cell comprising the photovoltaic semiconductor solution disclosed above comprising the steps of:
printing a positive electrode onto a substrate;
drying the positive electrode;
printing a positive membrane onto the positive electrode;
drying positive membrane;
printing an active PV layer comprising said photovoltaic semiconductor solution onto the positive membrane;
drying the active PV layer;
baking the active PV layer;
printing a negative membrane onto the active PV layer;
drying negative membrane;
printing at least one harvesting wire and a negative electrode onto the negative membrane;
drying the at least one harvesting wire and negative electrode; and
baking said solar cell where baking provides a hard and flat surface for said solar cell.

Further aspects of the invention will become apparent from consideration of the ensuing description of preferred embodiments of the invention. A person skilled in the art will realize that other embodiments of the invention are possible and that the details of the invention can be modified in a number of respects, all without departing from the inventive concept. Thus, the following drawings, descriptions and examples are to be regarded as illustrative in nature and not restrictive.

### BRIEF DESCRIPTION OF THE DRAWINGS

FIG. 1 is a side view of a print table for a solar cell according to the invention;

FIG. 2 is a schematic sectional view of a semiconductor solar cell according to the invention;

FIG. 3 is a flow chart illustrating the manufacture of the PV solution; and

FIG. 4 is a flow chart illustrating the manufacture of the solar cell.

### DETAILED DESCRIPTION OF THE INVENTION

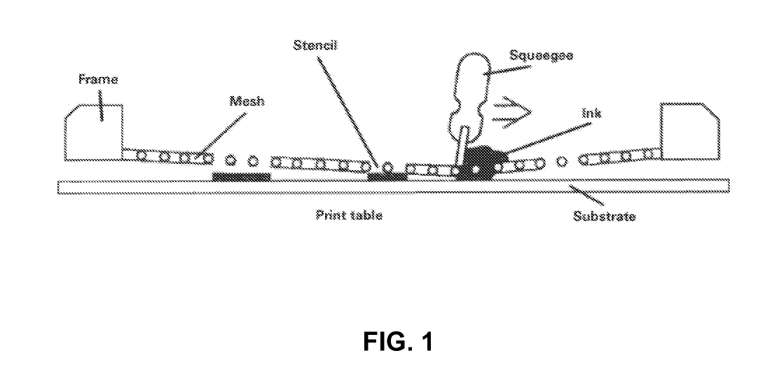

A typical screen printer that may be used in the printing of solar cells is illustrated in FIG. 1. Screen printing typically provides the most vibrant printing results compared to other available printing techniques known in the art, as the layer deposited is about 5-10 times thicker than results achieved using other printing techniques. The screen printing process is essentially a trough transfer process that utilizes a stencil as the medium for depositing each layer onto a substrate. With the aid of a squeegee, each layer is transferred through the prepared stencil to the substrate material beneath.

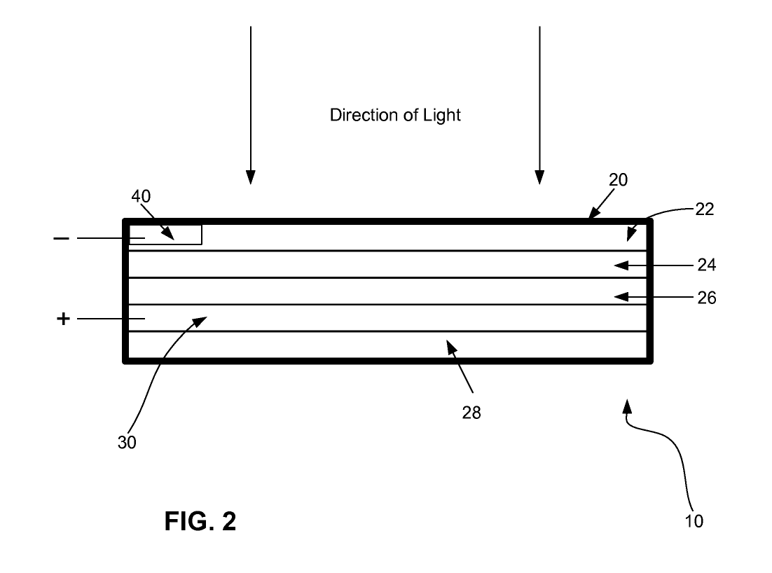

A semiconductor solar cell assembly 10 according to the present invention is shown in FIG. 2. The outer layer 20 of the solar cell 10 is a protective layer, generally made of a scratchproof material for example, a thermosetting resin or laminate. A current harvesting negative electrode 40, preferably made of argentum, is positioned below outer layer 20 and within negative membrane 22. In one embodiment, harvesting wires (not shown) are positioned over the surface of the negative membrane 22 and preferably the negative electrode 40 for the collection of the electricity. Negative membrane 22 enables the flow of charged free electrons to discharge to one of the harvesting wires and the negative electrode 40 and then return to the active PV layer 24. In one embodiment, these wires may be connected to each of the positive and negative electrodes. The harvesting wires are further connected to a battery, or similar device for storage of the collected electricity. The active PV layer 24 comprises a dried compound PV semiconductor solution, as disclosed below. Located below the active PV layer 24 is a positive membrane 26, which acts as an insulator and enables positive charges to discharge to a positive electrode 30 while also preventing the charged free electrons within the active PV layer 24 from flowing to the positive electrode 30. The positive electrode 30, preferably comprised of argentum, is a current collecting positive electrode. Each of the above layers rest on printing substrate 28, often referred to as the printing media, located below the positive electrode 30, which may be formed of a heat-resistant acetate, laminate, glass, or other material suitable for a printing substrate. These wires may be connected to the negative electrode.

The active PV layer 24 of the solar cell 10 is constructed from a compound PV semiconductor solution. The compound PV semiconductor solution is an equimolar mixture of cadmium (Cd) and tellurium (Te) powders, liquid gallium (Ga) and liquid indium (In) mixed in propylene glycol flux to create a viscous solution. This viscous solution is mixed with carbon (C) and resin in an organic solvent, and together contains semiconductor atoms in heterojunction. An example of the resin may be ADS61BFA (C₇₂H₁₄O₂) (Dupont) and an example of the organic solvent may be THF or chloroform. The PV semiconductor solution more specifically comprises a mesoporous structured nanocrystalline strontium titanate (SrTiO₃) coupled with at least one conjugated high molecular weight polymer for example, ADS300 (C₁₉H₂₆C₁₂O₂) (American Dye Source) to provide an effective concentration of free charge carriers. The mesoporous structure of the SrTiO₃ is preferably synthesized by hydrothermal treatment of nanocrystalline titanium dioxide semiconductor particles in the presence of strontium hydroxide (Sr(OH₂)), however a person skilled in the art would understand other methods may be used to achieve a similar resultant structure. The flat band potentials of the Fermi level of an illuminated semiconductor correlate with the solar cell's Voltage Open Circuit (V_{OC}), which is the difference of electrical potential between two electrodes of the solar cell when there is no external load connected. The mesoporous ternary SrTiO₃ contains atoms in a 6-fold octahedral coordination, which in conjunction with viscous CdTeCGaIn solution coupled with a conjugated high molecular weight polymer, for example ADS 300 (American Dye Source), provides an effective concentration of free charge carriers or electrons.

Light, including that from the sun, falls on the surface of the protective surface of the solar cell 10 of the present invention and passes through each of the layers of solar cell 10 disclosed above, to generate electrical power by photoelectric conversion. The semiconductor atoms of the active PV layer 24 have electrons orbiting their atomic centers. When light passes through the semiconductor atoms of the active PV layer 24, the positively charged atomic centers of the atoms pick up additional electrons and attempt to maintain these electrons orbiting the atomic centers. Once an atom reaches a point where the atomic center is no longer able to retain the orbiting electrons, at least one freely charged electron is released from the orbit of the atom. Charged electrons pass from the active PV layer 24 through to the negative membrane 22. On contacting one of the negative electrode 40 or the harvesting wire, the free charge is released and the electron is drawn back to the active PV layer 24. On release of the orbiting electrons from the atom, the positively charged atomic center may pass through the positive membrane 26 and contact the positive electrode 30 where the electric charge is harvested. The positive membrane 26 prevents the flow of charged electrons through to the positive electrode 30. In general, the harvesting wires are not connected to the positive electrode 30 as light does not travel through positive electrode layer as the positive electrode 30 is disposed behind active PV layer 24 and has no effect on the amount of light reaching the active PV layer 24. It is of particular importance that the negative electrode 40 is contacted by the harvesting wires as the negative electrode 40 is disposed above the active PV layer 24 and cuts the amount of incoming light that is received by the active PV layer 24.

### Manufacture of the PV Compound Semiconductor Printing Solution

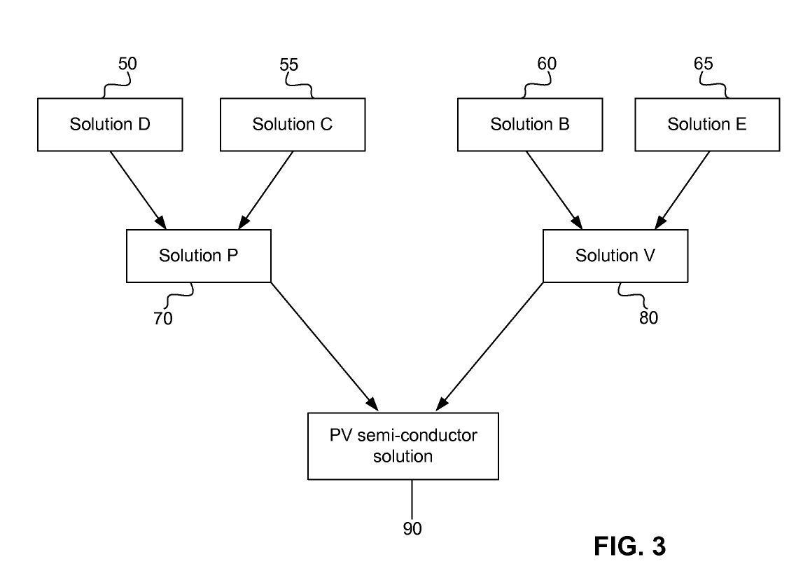

The PV compound semiconductor printing solution is manufactured in several stages as shown in FIG. 3. The process involves the creation of several individual solutions, more specifically solution B 60, solution C 55, solution D 50, and solution E 65 which are used later in the manufacturing of solution P 70 and solution V 80 which are then used in the final PV 10, semiconductor solution 90. More specifically, about 58-61 ml of solution D 50 is mixed with 1.5-1.75 g of solution C 55 to create solution P 70. About 50-55 ml of solution B 60 is mixed with about 45-50 ml of solution E 65 to create solution V 80. About 56-59 ml of solution P 70 is mixed with about 61-73 ml of solution V 80 to create the PV semiconductor solution 90.

The method of making each of the solutions is disclosed below. Each of the solutions is preferably stored under a nitrogen atmosphere. A nitrogen atmosphere, as described below, is typically an atmosphere from which oxygen has been removed and replaced by nitrogen at a pressure of about 1.1 ATM.

### Solution B:

Solution B is a combination of solutions B1 and B2 mixed with propylene glycol. More specifically, solution B comprises: at least one transition metal dissolved in a polar protic solvent; tellurium; a strong polar acid, preferably having a dielectric constant in the range of about 70-120; propylene glycol; and a stabilizing agent.

Even more specifically, solution B is a combination of solutions B1 and B2 described below and propylene glycol. Preferably, solution B comprises about 25-30 ml of solution B1 and about 22-25 ml of solution B2, each of which are stirred into about 10-18 ml of propylene glycol (C₃H₈O₂) at room temperature for a period of about 16-20 hours.

### Solution B1

Solution B1 comprises: a mixture of at least one transition metal, for example cadmium, zinc, or nickel, in the form of a salt dissolved in polar protic solvent, preferably water; a strong polar acid, preferably having a dielectric constant in the range of about 70-120; tellurium; and a polar aprotic solvent.

More specifically, solution B1 comprises about 22-27 mg of cadmium added to about 25 ml of distilled degassed water that has preferably been stirred under nitrogen for at least about 30 minutes, and is mixed for a period of about 30-40 minutes until the mixture is uniform. About 4-8 ml of sulphuric acid (H₂SO₄) is added to the mixture and stirred for at least about 6-8 hours at room temperature. The temperature of the mixture is then increased to about 45-49° C. and then stirred for a period of about 11-15 hours. About 12-15 mg of tellurium is added to the mixture and stirred for at least about 12 hours and not more than about 14 hours. About 30-40 ml of, dimethyl formamide (C₃H₇NO) is then added and stirred for about 6-8 hours, following which the mixture is cooled to about room temperature and then stirred for at least about 12 hours.

### Solution B2

Solution B2 comprises: a mixture of at least one transition metal, for example cadmium, zinc, or nickel, in the form of a salt dissolved in polar protic solvent, preferably water; propylene glycol; carbon; and a stabilizing agent, for example trioctylphosphine or a similar stabilizer able to stabilize particles in organic solvent. A person skilled in the art would understand that propylene glycol has properties similar to those of ethylene glycol and they may be used in place of one another.

More specifically, solution B2 is made by adding about 20-25 mg of cadmium sulfide (CdS) and about 11-15 mg of cadmium chloride (CdCl₂) to about 45-50 ml of distilled degassed water that has preferably been stirred under nitrogen for at least about 30 minutes, and then the mixture is stirred for a period of about 8-10 hours at room temperature. The temperature is then increased to about 37-41° C. and the mixture is then stirred for a period of about 8-10 hours. About 35-39 ml of propylene glycol (C₃H₈O₂) is added and the mixture stirred for about 6 hours and then cooled to about 30-33° C. About 11-14 mg of carbon (C) is then added and the mixture is stirred for about 4 hours. About 6-10 ml of trioctylphosphine ([CH₃(CH₂)₇]₃P) is then added and the mixture is cooled to about room temperature and then stirred for a period of about 5-10 hours.

### Solution C:

Solution C comprises:
a high molecular weight polymer;
a mixture of an ether, that acts as thickener and stabilizer;
solution C1; and
a resultant mixture comprising:
   the combination of titanium dioxide, suspended in a polar protic solvent (preferably water), having the pH adjusted by the addition of a quaternary ammonium salt:
   solution C2, and
   an alkali stabilizer, for example strontium hydroxide, strontium peroxide, magnesium oxide or similar stabilizer.

More specifically, solution C is a colloidal suspension of about 0.0161-0.0169 mol of suspended titanium dioxide (TiO₂) having a surface area of 182-188 m², which is equivalent to about 1.18-1.3 g of the suspension by weight, mixed in about 5-6 ml of distilled water. The pH of the suspension is adjusted to between about 11.5 to 13 by the addition of synthesized tetramethylammonium hydroxide (C₄H₁₃NO). Then about 3-4 ml of the C2 solution is added. About 2.04-2.09 g of strontium hydroxide ((Sr(OH)₂) is dissolved in about 50-55 ml of boiling distilled water, which is preferably degassed with nitrogen gas for at least about 30 minutes, to make strontium hydroxide solution. About 5-8 ml of the strontium hydroxide ((Sr(OH)₂) solution is then added to the suspension. On addition of the strontium hydroxide solution, the previously translucent titanium dioxide suspension turns milky white.

The suspension is stirred at room temperature for at least about 24 hours prior to autoclaving at about 190-199° C. for a period of about 10.5-13 hours. The resultant pressure of the suspension is between about 2 to 2.2 atmospheres. Approximately 1.5-1.6 g, more specifically 1.538-1.551 g of this suspension is then combined with about 1.36-1.42 g of a 10-13% solution of hydroxypropyl cellulose (HPC) in distilled water. About 4-5 ml of the C1 solution is then added.

The resultant mixture is then slowly evaporated using a rotary evaporator at room temperature until the resultant suspension contains about 50-54% colloid by weight. Typically, the average colloid molecular weight of the polymer is about 16.3×10⁴ and has a combining power equal to 1 gram-atomic weight of hydrogen. The suspension is then stirred while increasing temperature from room temperature to about 45-48° C. for a period of at least about 14 hours in a nitrogen atmosphere. In the nitrogen atmosphere, about 0.75-1 g of ADS300 conjugated polymer (American Dye Source) is then added to the mixture and stirred for at least about 9.5 hours, and then the temperature is reduced at 1.5-2° C. per hour until reaching room temperature.

### Solution C1

Solution C1 comprises: a mixture of at least one polar protic solvent soluable in water; at least one fatty acid; propylene glycol; and a cyanoethyl starch.

More specifically, solution C1 comprises a mixture of about 25-28% of butyl carbitol acetate (C₁₀H₂₀O₄), 10-12% of oleic acid (C₁₈H₃₄O₂) and 12-14% of propylene glycol (C₃H₈O₂) stirred at about room temperature for a period of about 4-5 hours. The mixture is then dissolved in about 90-100% cyanoethyl starch and stirred for about 12-14 hours.

### Solution C2

Solution C2 comprises a mixture of at least one polar aprotic solvent, a strong oxidizing agent having an ability to initiate radicals, and a non-polar aromatic hydrocarbon solvent, for example toluene, benzene, and naphthalene.

More specifically, solution C2 comprises a mixture of about 100-110 ml of 99-99.9% tetrahydrofuran (THF) stirred with about 50-55 grams of ammonium persulfate ((NH₄)₂S₂O₈) and about 7-9 ml of toluene (ACS) at room temperature for at least about 6 hours.

### Solution D:

Solution D comprises: at least one polar aprotic solvent; a polymer that acts as an electron acceptor, preferably PCBM (American Dyes); titanium dioxide; titanium isopropoxide; the salt of at least one alkali metal, for example cesium fluoride; and at least one non-polar solvent.

More specifically, solution D comprises about 41-45 ml tetrahydrofuran (THF) and about 0.41-0.5 g of 6,6-phenyl C71-butiric acid methyl ester thiophene pyrrole aniline monomer (PCBM) obtained from American Dyes™, mixed within a nitrogen atmosphere for a period of about 17-19 hours at room temperature. The temperature is increased to about 72-75° C. and then about 25-28 mg of nanocrystalline titanium dioxide (TiO₂) is added and the mixture is stirred for about 9-10 hours. The temperature is then slowly decreased by about 1.5-2° C. per hour to until a temperature of approximately about 60-64° C. is reached. About 15-19 mg of titanium isopropoxide (C₁₂H₂₈O₄Ti) and about 10-13 ml of 1,2 dichlorobenzene (C₆H₄Cl₂) is then added to the mixture and stirred for about 7-9 hours. The temperature is then decreased by about 3-3.5° C. per hour until a temperature of about 32-35° C. is reached and then about 7-8 mg of cesium fluoride (CsF), about 5-7 ml of THF and about 2-2.5 ml of 1,2 dichlorobenzene (C₆H₄Cl₂) are added to the mixture and stirred for a period of at least 18-21 hours. The mixture continues to be stirred and the temperature is decreased by about 1-2° C. per hour until room temperature is reached. The solution is preferably stored under a nitrogen atmosphere.

### Solution E:

Solution E is a combination of solution E1 and solution E2 and at least one semi-conductor non-metal, for example selenium, having photovoltaic and photoconductive properties that conducts electricity better in light.

More specifically, solution E comprises approximately equal amounts of solution E1 and solution E2 mixed for at least about 11 hours. About 10-12 mg of selenium is then added to the mixture at room temperature. The temperature is then increased to about 77-81° C. and the mixture is then stirred for at least about 8 hours. The mixture is then stirred and cooled slowly by about 4-4.5° C. per hour until reaching room temperature.

### Solution E1

Solution E1 comprises: a strong polar acid, preferably having a dielectric constant in the range of about 70-120; a polar protic solvent, preferably water; at least one highly conductive metal, for example copper, bronze, silver, or nickel; at least one semi-metal, for example gallium; at least one poor metal, for example indium; and a non-polar solvent.

More specifically, solution E1 comprises about 10-14 ml of sulphuric acid (H₂SO₄) added to about 60-64 ml of distilled degassed water that has preferably been stirred under nitrogen for at least 30 minutes, and the mixture is stirred for about 55-59 minutes. About 40-43 mg of copper (Cu) and about 10-12 ml of chloroform (CHCl₃) is then added and the mixture is stirred for a period of about 7-9 hours at room temperature. The temperature is then increased to about 82-86° C. and the mixture is stirred for about 9-11 hours. The temperature is then slowly decreased by 2-3° C. per hour to a temperature of about 71-75° C. About 32-35 ml of liquid gallium is added to the mixture and then stirred for a period of about 8.5-9.5 hours. About 5-7 ml of liquid indium (In) is added and the temperature is then slowly decreased by 2-3° C. per hour until reaching room temperature.

### Solution E2

Solution E2 comprises a mixture of at least one transition metal, for example iridium and platinum, at least one non-polar solvent, and cesium oxide which acts as a conductor and electron donor.

More specifically, solution E2 comprises about 30-33 mg of iridium (Ir) added to about 20-23 ml of distilled degassed water that has preferably been stirred under nitrogen for at least about 30 minutes, then about 15-17 ml of ethyl acetate (C₄H₈O₂) is added and the mixture is stirred at a temperature of about 38-41° C. for at least about 10.5 hours. About 8-11 mg of cesium oxide (Cs₂O) is then added and the mixture stirred for at least about 6-8 hours. About 10-15 ml of chlorobenzene (C₆H₅Cl) is added and the mixture is stirred and slowly evaporated, for example using a rotary evaporator, and cooled by about 2-3° C. per hour until reaching room temperature and the suspension contains about 78-81% colloid by weight.

### Solution P:

Under a nitrogen atmosphere, about 58-61 ml of solution D and about 1.5-1.75 g of solution C are mixed for a period of about 24-27 hours at room temperature. The resultant solution is preferably stored under the nitrogen atmosphere.

### Solution V:

About 50-55 ml of solution B and about 45-50 ml of solution E are mixed for a period of about 7-9 hours at room temperature. The temperature is then increased to about 66-69° C. and the mixture is then stirred for about 6-7 hours. The temperature is then slowly decreased by 3-4° C. per hour until reaching room temperature and then the mixture is stirred for about 7-9 hours. The resultant solution is preferably stored under a nitrogen atmosphere.

### Solution PV:

Under a nitrogen atmosphere, about 56-59 ml of solution P and about 61-73 ml of solution V are mixed for a period of about 4-5 hours at room temperature. The temperature is then increased to about 47-49° C. and the mixture is then stirred for about 6-7 hours. The temperature is then slowly decreased by 2-3° C. per hour until reaching room temperature and the mixture is then stirred for at least about 8.5 hours. The resultant solution is preferably stored under a nitrogen atmosphere.

The resultant solution is stored under a nitrogen atmosphere and is stable for a period of about 1 year at a temperature between about 5 to 40° C.

### Manufacture of the Positive Membrane Solution:

The positive membrane solution comprises: a mixture of a conducting polymer; a stabilizing agent, for example trioctylphosphine or a similar stabilizer able to stabilize particles in organic solvent; and a dielectric composition, such that the resultant solution on drying acts as an insulator layer. A person skilled in the art would understand that any insulator having the same properties would be suitable.

More specifically, the positive membrane solution comprises a mixture of about 48-52 ml of Baytron SV™ (9,9 dixexyl-dibromofluorene) (HCStarck) added into about 6-8 ml of trioctylphosphine ([CH₃(CH₂)₇]₃P) and stirred for a period of about 7-8 hours at room temperature. About 5-7 ml of a dielectric composition, preferably electrodrag 8153™ (Dupont), is then added and the mixture is stirred for at least about 11-13 hours. The resultant solution is preferably stored under a nitrogen atmosphere.

### Manufacture of the Negative Membrane Solution:

The negative membrane solution comprises: a conducting monomer; a polar aprotic solvent; a stabilizing agent, for example trioctylphosphine or a similar stabilizer able to stabilize particles in organic solvent; and a dielectric composition.

More specifically, the negative membrane solution comprises about 50-53 ml of Baytron HC™ (3,4 ethylenedioxythiophene) (HCStarck) mixed with about 6-8 ml of dimethyl formamide (C₃H₇NO) and 3-5 ml of trioctylphosphine ([CH₃(CH₂)₇]₃P) at room temperature, for a period of about 7-9 hours. About 7-8 ml of a dielectric composition, preferably dielectric 5018 green (Dupont), is then added and the mixture is stirred for about 12-13 hours. The resultant solution is preferably stored under a nitrogen atmosphere.

### Manufacture of the Electrodes:

The electrodes are prepared using metallic powders, for example silver, copper, nickel or aluminium, mixed with a viscous agent. More preferably, the electrodes are prepared using silver powders combined with a viscous agent, mixed and then dried.

In one embodiment, the electrodes are constructed as follows. At room temperature, about 48-52 ml of Ag 5000™ (Dupont), comprising about 30-60% silver, about 10-30% dimethyl glutarate, about 10-30% dimethyl succinate and about 5-10% vinyl polymer, is mixed with about 10-12 ml of one of Dupont 7164, a translucent conductor, or 8211™ thinner, an aromatic hydrocarbon mixture (Dupont) and a catalytic reformer fractionator residue (CAS 68477-31-6), for at least about 1 hour. About 5-7 mg carbon, preferably 5928 carbon (Dupont) is then added and the mixture stirred for a period of about 15-17 hours. The resultant solution should have a viscosity in the range of about 70-75 mPa/s to about 85-90 mPa/s. Where the resultant solution falls outside the desired viscosity range an additional amount of 8211 thinner may be added as necessary until the desired viscosity is achieved, and the solution is then stirred for at least about 1 hour. On drying, the electrodes may be deposited on a copper layer and dried and baked to facilitate ease soldering of harvesting wires.

Harvesting wires may be constructed from the same solution used in manufacture of the electrodes or alternatively, from any material suitable for the harvesting of electric energy such as copper, nickel or aluminium.

### Manufacture and Assembly of the Solar Cell:

Printing of the solar cell preferably uses five print stations and seven dryer stations. Each print station comprises a screen printer, preferably a MNR screen printer. However, a person skilled in the art would understand that any screen printer would be effective in the printing of the solar cell of the present invention. Each dryer station comprises a drying device capable of drying the printed material sufficiently that the printed layer is dry to the touch. More specifically, each of the printed layers is sufficiently dry that as the layers are printed one atop of the next, there is no interaction or mixing of the individual layers with one another. In one embodiment, the drying stations are ultraviolet (UV) dryers however, a person skilled in the art would understand that any dryer would be effective in the drying of the solar cell of the present invention.

In one embodiment, each layer of the solar cell is deposited through a mesh screen onto the substrate, and each layer is at least dried. In another embodiment, at least the active PV layer is baked prior to the next layer being applied. Preferably, the active PV layer is baked in a convection oven, more specifically a zenon quartz infrared convection oven. Drying of the active PV layer creates a layer which is dry to the touch, however, the layer may have imperfection and may not be smooth. Baking of the active PV layer ensures the layer has a hard, flat finished surface. In addition, as the active PV layer includes a polymer which is an organic material, this material is capable of growth and expansion. Baking ceases any growth the ensure the surface of the active PV layer remains a hard and flat surface, which is of particular importance in a solar cell as pinholes and inconsistencies in the layer may cause internal short circuits or current leakage and decrease the performance of the solar cell.

Once each of the layers is deposited and dried, harvesting wires are printed and dried on the surface of the negative membrane and, in one embodiment the negative electrode, and these wires are attached to each of the positive and negative electrodes. In one embodiment, the harvesting wires and negative electrode are printed simultaneously and are a single printing pattern on the mesh screen. In one embodiment, the harvesting wires may be coated with copper to facilitate ease of soldering the harvesting wires to a contact. After each of the layers is deposited and dried, the solar cell is then baked and laminated to protect the solar cell from scratching.

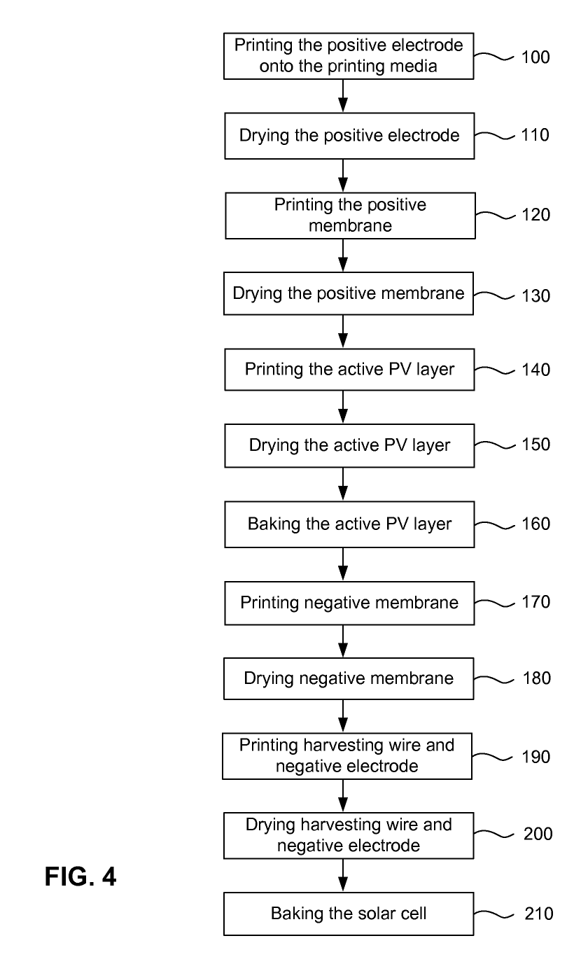

A method of manufacturing the solar panel described above, is illustrated in FIG. 4. The method utilizes a screen printing process and includes the steps of:
Printing the positive electrode 30 onto a substrate or printing media 28 (step 100);
Drying the positive electrode 30 (step 110);
Printing the positive membrane 26 onto the positive electrode 30 (step 120);
Drying positive membrane 26 (step 130);
Printing the active PV layer 24 onto the positive membrane 26 (step 140);
Drying the active PV layer 24 (step 150);
Baking the active PV layer 24 (step 160);
Printing negative membrane 22 onto the active PV layer 24 (step 170);
Drying negative membrane 22 (step 180);
Printing harvesting wire and negative electrode 40 onto the negative membrane 22 (step 190);
Drying harvesting wire and negative electrode 40 (step 200); and
Baking the solar cell 10 (step 210).

Each of the layers of the solar cell may vary in the thickness of the individual layers, however, each of the layers is generally at least about 10-12 microns thick. In one embodiment, the negative membrane is a conducting monomer enabling one-way travel of the current or charged free electrons to either the negative electrode or active PV layer. The negative membrane may preferably exhibit a resistance of about 350 ohms. In another embodiment, the positive membrane is a conducting polymer and acts as a diode or triode enabling an electric current to pass from the positive membrane to the positive electrode and at the same time blocking the flow of charged free electrons from flowing from the active layer to the positive electrode. The positive membrane may preferably exhibit a resistance of about 1000 ohms. In another embodiment, the different in the resistance on comparison of the resistance of the negative membrane and the positive membrane is about 500-600 ohms, where the negative membrane has a lesser resistance that the positive membrane.

Harvesting wires, when connected to at least the negative electrode, collect the electric current generated on light hitting the solar cell. These harvesting wires are connected to the negative electrode, for example by soldering. In addition, these harvesting wires may be further connected to a contact, for example a wire, and then further connected to a battery through battery charger or alternative storage device.

In one embodiment, solar cells may be connected in series or in parallel depending on the desired end use. Connection in series is similar to batteries placed head to tail through a series lineup such that solar cells connected in series have the positive (+) output of a solar cell connected to the (−) output of an adjacent solar cell and so on. Series connection adds the voltage produced from each of the solar cells connected in the series. In an alternate embodiment, solar cells may be connected in parallel. In parallel connection, all the negative outputs of the solar cells are connected together and all the positive outputs of the solar cells are connected together. Parallel connection of a group of solar cells does not alter the voltage generated, but enables a greater current capacity.

Although the particular preferred embodiments of the invention have been disclosed in detail for illustrative purposes, it will be recognized that variations or modifications of the disclosed apparatus and method lie within the scope of the present invention. For example, throughout this document when quantities of different compounds are mixed, larger or smaller quantities of the same solutions can be mixed as long as the ratio between the compounds is approximately maintained.

The invention claimed is:

1. A photovoltaic semiconductor solution comprising at least:
an equimolar mixture of cadmium, tellurium, gallium and indium;
propylene glycol flux;
carbon;
resin in an organic solvent;
strontium titanate; and
high molecular weight polymer;
wherein said photovoltaic semiconductor solution provides charged free electrons on application of light to said photovoltaic semiconductor solution.

2. A photovoltaic semiconductor solution according to claim 1, wherein the equimolar mixture is combined with the propylene glycol flux, carbon and resin and the resultant mixture in conjunction with the strontium titanate is coupled to the high molecular weight polymer.

3. A solar cell comprising:
a first electrode layer and a second electrode layer;
a photo voltaic (PV) semiconductor layer disposed between the first and second electrodes;
a first membrane disposed between the first electrode and the semiconductor layer;
a second membrane disposed between the second electrode and the semiconductor layer;
wherein the first membrane is an electron acceptor layer and the second membrane in an insulator;
wherein the PV semiconductor layer includes a PV semiconductor solution comprising at least an equimolar mixture of cadmium, tellurium, gallium and indium;
wherein each of the layers are formed on a substrate; and photoelectric power is generated due to light that is incident from the first electrode layer.

4. A solar cell according to claim 3, wherein said PV semiconductor layer includes a PV semiconductor solution further comprising:
propylene glycol flux;
carbon;
resin in an organic solvent;
strontium titanate; and
high molecular weight polymer;
wherein said photovoltaic semiconductor solution provides charged free electrons on application of light to said photovoltaic semiconductor solution.

5. A solar cell according to claim 3, wherein said first and second electrode layer comprise at least one metallic powder and a viscous agent.

6. A solar cell according to claim 3, wherein said at least one metallic powder is selected from the group consisting of silver, nickel, copper and aluminium.

7. A solar cell according to claim 3, wherein at least one said metallic powder is silver.

8. A solar cell according to claim 3, wherein said first electrode is a negative electrode.

9. A solar cell according to claim 3, wherein said second electrode is a positive electrode.

10. A solar cell according to claim 3, wherein said first membrane comprises a conducting monomer, a polar aprotic solvent, a stabilizing agent, and a dielectric composition.

11. A solar cell according to claim 3, wherein said second membrane comprises a conducting polymer, a stabilizing agent, and a dielectric composition.

12. A method of manufacturing a photovoltaic semiconductor solution comprising the steps of:
making a first solution comprising at least one transition metal dissolved in a polar protic solvent; tellurium; a strong polar acid, preferably having a dielectric constant in the range of about 70-120; propylene glycol; and a stabilizing agent;
making a second solution comprising
solution 2A comprising a high molecular weight polymer; and an ether, that acts as thickener and stabilizer;
solution 2B comprising a mixture of at least one polar protic solvent
soluable in water; at least one fatty acid; and propylene glycol; and dissolving said solution 2B in a cyanoethyl starch; and
solution 2C comprising
solution 2C-1 comprising titanium dioxide, suspended in a polar protic solvent having the pH adjusted by the addition of a quaternary ammonium salt;
solution 2C-2 comprising at least one polar aprotic solvent, a strong oxidizing agent having an ability to initiate radicals, and a non-polar aromatic hydrocarbon solvent; and
an alkali stabilizer;
making a third solution comprising at least one polar aprotic solvent; a polymer that acts as an electron acceptor; titanium dioxide; titanium isopropoxide; the salt of at least one alkali metal; and at least one non-polar solvent;
making a fourth solution comprising
solution 4A comprising a strong polar acid, a polar protic solvent; at least one highly conductive metal; at least one semi-metal; at least one poor metal; and a non-polar solvent;
solution 4B comprising at least one transition metal; at least one non-polar solvent; and cesium oxide; and
at least one semi-conductor non-metal that is photovoltaic and photoconductive;
making said fifth solution comprising mixing at least between about 58-61 ml of said third solution and between at least about 1.5-1.75 g of said second solution;
making said sixth solution comprising mixing at least between about 50-55 ml of said first solution and between at least about 45-50 ml of said fourth solution; and
making said photovoltaic semiconductor solution comprising mixing at least between about 56-59 ml of said fifth solution and at least between about 61-73 ml of said sixth solution;
wherein each of the solutions is preferably stored in a nitrogen atmosphere.

13. A method of manufacturing a photovoltaic semiconductor solution comprising the steps of:
making a first solution comprising
between about 25-30 ml of solution 1A comprising between about 22-27 mg cadmium, distilled water, between about 4-8 ml sulphuric acid, between about 12-15 mg tellurium and between about 30-40 ml dimethyl formamide; and
between about 10-18 ml of solution 1B comprising 20-25 mg cadmium sulphide, 11-15 mg cadmium chloride, distilled water, 35-39 ml propylene glycol, 11-14 mg carbon and 6-10 ml trioctylphosphine;
making second solution comprising
solution 2A comprising between about 0.75-1 g of a high molecular weight polymer; and between about 1.36-1.42 g of a 10-13% solution of hydroxypropyl cellulose (HPC) dissolved in distilled water;
between about 4-5 ml of solution 2B comprising between about 25-28% of butyl carbitol acetate, between about 10-12% of oleic acid and between about 12-14% of propylene glycol; and dissolving said solution 2B in about 90-100% cyanoethyl starch;
between about 1.5-1.6 g of solution 2C comprising
solution 2C1 comprising between about 1.18-1.3 g of titanium dioxide suspended in distilled water, having the pH adjusted by the addition of tetramethylammonium hydroxide;
solution 2C2 comprising between about 100-110 ml of 99-99.9% tetrahydrofuran, between about 50-55 g of ammonium persulfate and between about 7-9 ml of toluene;
solution 2C3 comprising between about 5-8 ml strontium hydroxide suspended in distilled water;
making a third solution D comprising between about 41-45 ml tetrahydrofuan, 0.41-0.5 g PCBM, 25-28 mg titanium dioxide, 15-19 mg titanium isopropoxide, 10-13 ml 1,2 dichlorobenzene and 7-8 mg cesium floride;
making a fourth solution comprising
solution 4A comprising between about 10-14 ml sulphuric acid, distilled water, between about 40-43 mg copper, between about 10-12 ml chloroform, between about 32-35 ml gallium and between about 5-7 ml indium;
solution 4B comprising between about 30-33 mg iridium, distilled water, between about 15-17 ml ethyl acetate, between about 8-11 mg cesium oxide and between about 10-15 ml chlorobenzene;
mixing between about 10-12 mg selenium and about equal parts of said solution 4A and said solution 4B;
making said fifth solution comprising mixing at least between about 58-61 ml of said third solution and between at least about 1.5-1.75 g of said second solution;
making said sixth solution comprising mixing at least between about 50-55 ml of said first solution and between at least about 45-50 ml of said fourth solution; and
making said photovoltaic semiconductor solution comprising mixing at least between about 56-59 ml of said fifth solution and at least between about 61-73 ml of said sixth solution;
wherein each of the solutions is preferably stored in a nitrogen atmosphere.

14. A method of manufacturing a solar cell comprising said photovoltaic semiconductor solution of claim 3 comprising the steps of:
printing a positive electrode onto a substrate;
drying the positive electrode 30;
printing a positive membrane onto the positive electrode;
drying positive membrane;
printing an active PV layer comprising said photovoltaic semiconductor solution onto the positive membrane;
drying the active PV layer;
baking the active PV layer;
printing a negative membrane onto the active PV layer;
drying negative membrane;
printing at least one harvesting wire and a negative electrode onto the negative membrane;
drying the at least one harvesting wire and negative electrode; and
baking said solar cell wherein said baking provides a hard and flat surface for said solar cell.
